(19) United States
(12) Patent Application Publication
(10) Pub. No.: US 2007/0082598 A1
(43) Pub. Date: Apr. 12, 2007

(54) Module frame for receiving electronic plug-in modules

(75) Inventors: Heinz Kempf, Calw-Altburg (DE); Heinz Euchner, Birkenfeld (DE); Hans-Ulrich Gunther, Pfinztal (DE)

Correspondence Address: IP SECTION;GARDERE WYNNE SEWELL LLP, 3000 THANKSGIVING TOWER, 1601 ELM STREET, SUITE 3000, DALLAS, TX, 75201, US

(73) Assignee: Schroff GmbH, Straubenhart (DE)

(21) Appl. No.: 11/378,141

(22) Filed: Mar. 17, 2006

(30) Foreign Application Priority Data
Mar. 18, 2005 (DE) 202005004448.2

(51) Int. Cl. H05K 5/00

(52) U.S. Cl. 454/184

(57) ABSTRACT

A housing for holding electronic plug-in modules includes an installation space open toward the front side of the housing for plug-in modules, an air suction space under the installation space, and a fan space above the installation space, in which at least two radial-flow fans are arranged one behind the other. Cooling air flows through the installation space essentially in the vertical direction, and at least a front mounted radial-flow fan is arranged at an angle, so that the exhaust-air flow of the front mounted radial-flow fan flows generally over a rear mounted radial-flow fan.

The present invention relates to a housing or module frame for holding or receiving electronic plug-in modules, with installation space open toward the front side of the housing for the plug-in modules, an air suction space under the installation space, and a fan space above the installation space, in which at least two radial-flow fans are arranged one behind the other. Cool air flows through the installation space essentially in the vertical direction.

Several such housings are typically installed in switching cabinets. To be able to hold as many housings as possible in one switching cabinet, the individual housings should be as small as possible. The smaller the overall height of the housing, the better the available space in the switching cabinet can be used. In this way, the costs related to the floor space of the switching cabinet can be reduced. However, at the same time, the packing density of the electronic plug-in modules is continuously increasing due to advances in miniaturization. An increasing number of modules are being placed in smaller and smaller spaces. Thus, the power loss to be dissipated from the plug-in modules is constantly increasing. This results in special cooling requirements for the module carrier and the housing.

Especially in the field of telecommunications devices, cooling requirements have increased very strongly and will continue to increase in the future. The ATCA standard (Advanced Telecom Computing Architecture) developed for telecommunications applications by PICMG (PCI Industrial Computing Manufacture Group) permits power loss of up to 200 W per plug-in module. Typically, in one housing for telecommunications applications, 14 to 16 plug-in modules are placed one next to the other. Thus the total power loss is around 3000 W. To prevent the housing from overheating, this heat energy must be dissipated in an effective and fail-safe way.

The ever increasing power loss stands diametrically against the requirement for an overall height that is as small as possible. To dissipate the heat generated in the module carrier or housing, the cooling output of the cooling system must be increased. This requires the largest and most powerful fans possible. However, more powerful fans accordingly require more space. At the same time, a high cooling output requires large air inlet and outlet cross sections, as well as an air guide shaped favorably for flow with the smallest possible air resistance within the housing. Because the height of the installation space for the plug-in modules is fixed by the standard, the overall height of the housing can be reduced only when the space for the fans is reduced as much as possible. However, this is not possible without additional measures if a very large cooling output is required and a correspondingly more powerful fan with larger dimensions must be used.

As an additional requirement, a system availability of at least 99.999% is expected by the telecommunications systems. Such a high fail-safe performance of a few minutes per year in systems in long-term operation can be guaranteed only with redundant systems. Like all the other important components of a telecommunications system according to the AT-CA standard, the fans must also be designed with multiple redundancy.

From a physical viewpoint, ideal ventilation is generated by a fan with a maximum size. The total efficiency is then greater than for the use of several small fans. However, several small fans reduce the risk of overheating if a single fan fails. If a fan fails, the remaining air output must always be sufficient so that it does not lead to overheating of the system. The air volume reserve must be sufficiently large. Here, a more efficient and technically more useful compromise must be sought between the highest possible air output during normal operation and lowest possible loss of cooling power if a fan fails.

Telecommunications systems in which several small fans are arranged under the plug-in modules in the housing are known. These fans configured as axial-flow fans draw cool air and force it upward onto the plug-in modules. Because incoming cooled air flows around the fans, their temperature load is low, which has a positive effect on the service life. Housings in which axial-flow fans are arranged above the plug-in modules are known. However, a disadvantage here is that a relatively large space must be made available above the fans so that the exhaust air can be effectively drawn away from the plug-in modules and it does not result in dead air. However, this runs against the requirement for the smallest possible overall height of the overall system.

Instead of axial-flow fans, in the state of the art radial-flow fans are also used which already include a 90° deflection of the air flow due to their construction. The exhaust air drawn from below is blown out to the side. Therefore, no additional space must be made available above the fans. However, because several fans should be used for reasons of redundancy, the fans must be arranged offset in height, so that the exhaust air flows can flow away from the fans unimpaired at the sides, without being impaired by other fans. The more fans that are installed in a row, the greater the necessary height offset of the individual fans relative to each other. The required space for the arrangement of fans must have a height that corresponds to a multiple of the height of a single fan.

A module carrier in which a total of four radial-flow fans are arranged in the fan space above the plug-in modules is produced, for example, by the company Rittal. Each radial-flow fan is installed in a separate capsule. The four radial-flow fans are arranged in two rows, with the front row being mounted above the rear row. Through this arrangement, the fans can be individually exchanged. If one fan fails, 75% of the total cooling output is still available. The exhaust air flow of the front fans is not negatively affected by the rear fans because the exhaust air of the front fans is led away in the horizontal direction above the rear fans. However, this has the disadvantage that the necessary space for the fans must be twice as high as for a single fan cassette.

### SUMMARY OF THE INVENTION

The problem of the present invention is to devise a housing for holding electronic plug-in modules which has the smallest possible overall height but nevertheless holds several fans for generating a maximum cooling output.

To solve the problem, the invention provides a housing or frame for receiving and holding electronic modules that has an installation space open toward the front side of the housing for plug-in modules, an air suction space under the installation space, and a fan space, which lies above the installation space and in which at least two radial-flow fans are arranged one behind the other. Cool air flows through the installation space essentially in the vertical direction.

Also, according to the invention, at least the front radial-flow fan is arranged at an angle so that the exhaust air of the front radial-flow fan flows away essentially above the rear radial-flow fan. By inclining the front radial-flow fan, its exhaust air is not deflected against the rear fan arranged behind the front fan. The inclination must be selected so that the exhaust air flow essentially flows past the rear fan; thus no unnecessary turbulence is created and the air output of the exhaust air flow of the front radial-flow fan is not impaired by the rear fan. In addition, such an arrangement prevents the motor of the rear fan from being heated also by the hot exhaust air flow of the front fan.

In another advantageous embodiment of a housing according to the invention, the rear radial-flow fan is arranged essentially horizontally, while the front radial-flow fan is inclined by an acute angle relative to the horizontal. Thus, the outflow opening of the front fan facing the rear radial-flow fan is increased. The exhaust air flow of the front fan is deflected above the rear fan. The axis of the front radial-flow fan is tilted forward from the vertical, while the axis of the rear fan is essentially vertical. Through the inclined arrangement of the front radial flow, the necessary overall height of the fan space increases only relatively slightly in comparison to the fans arranged horizontally one behind the other. The additional requirement for vertical height is dependent on the degree of inclination of the front radial-flow fan. The inclination angle is determined, in turn, by the diameter and the overall height of the radial-flow fans that are used. For two radial-flow fans arranged offset at an angle one behind the other, the fan space increases only by approximately 50% relative to 100% for fans arranged one above the other. Thus, the spatial requirements are significantly less overall than for two radial-flow fans, which are offset in height and which are both aligned horizontally.

An inclination angle of the front radial-flow fan between 10° and 40° relative to the horizontal is especially preferred. In practical use, an inclination angle of about 30° has proven to be especially preferred. The optimum inclination angle is dependent on the overall height and the size of the individual fan. If more than two fans are used in the housing, the rear radial-flow fan is arranged essentially horizontally. The other fans are inclined relative to the horizontal, with the inclination increasing the closer the radial-flow fan is positioned to the front side of the housing. The optimum inclination of the individual fans also depends on the position and size of the later air outlets.

Advantageously, each radial-flow fan has a separate air guide space. The exhaust air flows of the two radial-flow fans are completely separated from each other, which rules out mixing of the exhaust air flows. Absolutely no turbulence or pneumatic short circuits are produced, which could occur especially when the exhaust air flows have different temperatures. The cooling output and the effectiveness of the radial-flow fans are further increased.

An embodiment of the housing according to the invention in which the fan space holds several cassettes one next to the other, with each cassette containing at least one front radial-flow fan and one rear radial-flow fan, has proven to be especially advantageous. The cassettes can be pushed in and out independently of each other. Each cassette can be exchanged individually. If a single fan fails, one of the cassettes can be removed from the housing, and the fan can be replaced. The other fans or cassettes are not affected by the exchange. Preferably, the cassettes have dividing plates on their sides so that the air flows in the individual cassettes are decoupled from each other. There is no reaction from air guidance in one cassette on other cassettes.

In a preferred embodiment of the housing, the air suction space in the region of the front side of the housing has an air inlet. Fresh air is led through the air inlet of the front side into the housing. The air is then drawn by the fan located above the installation space and flows essentially vertically past the plug-in modules or upward through these modules. The arrangement of the air inlet regions at the front side of the housing has the advantage that they are freely accessible and can be cleaned using simple means and methods if they become dirty. It is also guaranteed that sufficient air can flow into the housing, because the front side of the housing as a rule remains free.

Preferably, the air outlet is located in the region of the rear side of the housing. The air drawn by the fans from below is deflected about 90° by the radial-flow fans and fed essentially horizontally through the ventilation channels to the air outlet.

The invention is explained in more detail below with reference to the drawing figures.

### BRIEF DESCRIPTION OF THE DRAWINGS

FIG. 1 is a cross section through a housing or frame according to the invention with an installation space, a suction space, and a fan space; and

FIG. 2 is a perspective view of the housing of FIG. 1.

### DETAILED DESCRIPTION OF A PREFERRED EMBODIMENT

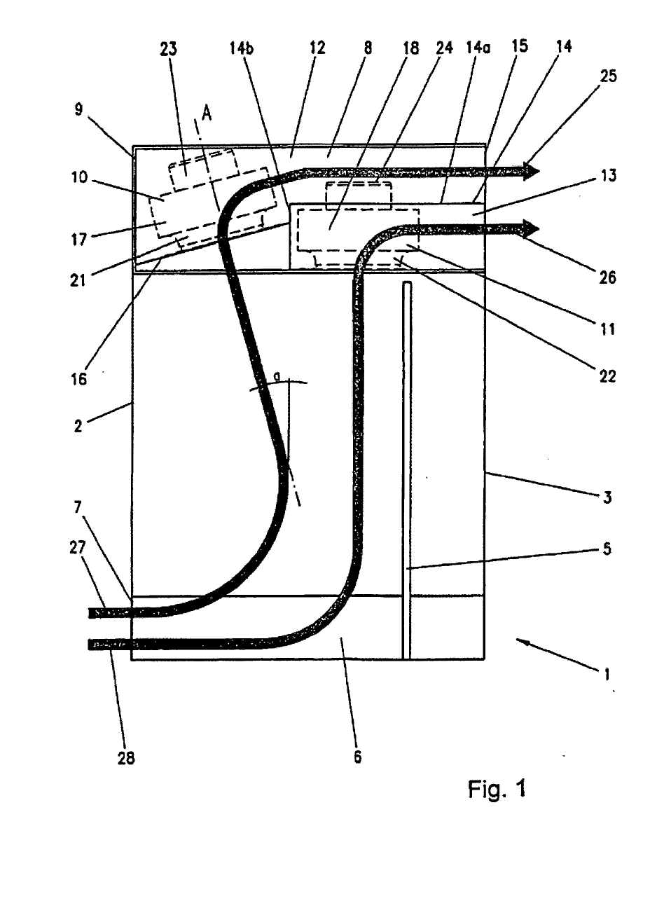

Referring to FIG. 1, a housing 1 with its front side 2 and its rear side 3 is shown in section. An installation space 4 is open toward the front side 2 of the housing 1. The installation space 4 is used for holding electronic plug-in modules which are pushed in from the front side 2 into the installation space 4. In the region of the rear side 3 of the installation space 4, there is a rear wiring board, the so-called backplane 5. The (not shown) plug-in modules are plugged into this backplane 5.

Underneath the installation space 4, there is an air suction space 6. The backplane 5 projects into the rear region of the air suction space 6. In the region of the front side 2, the air suction space 6 has an air inlet 7 through which fresh air can flow into the housing. Above the installation space 4, there is a fan space 8. In the fan space 8, there are cassettes 9, which include two radial-flow fans 10, 11. The front radial-flow fan 10 is offset at an angle in front of the rear radial-flow fan 11.

The cassette 9 is divided by dividing plates into a front air guidance space 12 and a rear air guidance space 13. The rear air guidance space 13 is formed by an L-shaped air guide plate 14. The long L-leg 14a of the air guide plate 14 is aligned horizontally. Its length corresponds to approximately 60% of the total depth of the housing 1. The short L-leg 14b of the air guide plate 14 extends vertical to the base of the cassette 9. The length of the short L-leg 14b of the air guide plate 14 corresponds to half the height of the cassette 9.

On the rear side 3 of the housing 1, the fan space 8 has an air outlet 15, through which the hot exhaust air is blown out from the housing 1. The cassettes 9 are open at the back. Thus, the air forced through the air guidance spaces 12, 13 of the cassettes 9 can escape into the surroundings.

The front radial-flow fan 10 is mounted on a mounting plate 16. The mounting plate 16 is tilted at an inclination angle α from the horizontal. Consequently, the fan axis A of the front radial-flow fan 10 is tilted by the same angle α from the vertical. The inclination angle α is 30° in the present example. The mounting plate 16 is mounted between the short L-leg 14b of the air guide plate 14 and the front side of the cassette 9. In this way, the mounting plate 16 is attached a few millimeters away from the base of the cassette 9 at the front side of the cassette 9. The opposite end of the mounting plate 16 is attached close to the upper end of the short L-leg 14b of the air guide plate 14.

The radial-flow fans 10, 11 each have a fan wheel 17 and 18, respectively. Underneath the fan wheels 17, 18 there are suction heads 21 and 22, respectively, which draw air in the axial direction. Above the fan wheels 17 and 18, there are the motor housings 23 and 24, respectively, in which the motors for driving the radial-flow fans 10, 11 are located.

The motor housing 24 of the rear radial-flow fan 11 projects through the air guide plate 14 into the front air guidance space 12. The height of the rear air guidance space 13 is thus less than the overall height of the rear radial-flow fan 11.

The inclination angle α of the mounting plate 16 and also the height of the mounting plate 16 above the horizontal are determined by the geometry of the two radial-flow fans 10, 11. The front radial-flow fan 10 is offset at an angle, so that its exhaust air flow 25 flows essentially above the motor housing 24 of the rear radial-flow fan 11. The exhaust air flow 26 of the rear radial-flow fan 11 flows completely in the horizontal direction. An imaginary line running parallel to the bottom side of the air wheel 17 of the front radial-flow fan 10 ends approximately at the front top corner of the motor housing 24 of the rear radial-flow fan 11. So that the exhaust air flow 25 of the front radial-flow fan 10 runs horizontally as much as possible, the inclination angle α is kept as small as possible. The exhaust air flow 25 should be deflected at an angle that is as acute as possible against the cover of the housing 1, so that as little turbulence as possible is generated. Here, a compromise of inclination angle α, height of the mounting plate 16, and overall height of the cassette 9 is sought. The height of the cassette 9 corresponds to twice the height of the rear air guidance space 13.

In FIG. 1, the main air flow paths of the cooling air or the exhaust air are also shown. The cooling air flows through the air inlet 7 at the front side 2 into the air suction space 6 and then divides into the two cooling air flows 27 or 28. These flow upward from below through the installation space 4 essentially vertically and in this way cool the (not-shown) plug-in modules inserted into the backplane 5. The cooling air flows 27, 28 are drawn by the radial-flow fans 10 and 11, respectively. The front cooling air flow 27 is deflected in the top region of the installation space 4 in the direction of the fan axis A of the front radial-flow fan 10, so that it enters axially into this fan. The air entering the radial-flow fan 10 axially is blown out by the fan wheel 17 radially and flows in the direction of the air outlet 15 via the motor housing 24 of the radial-flow fan 11.

The rear cooling air flow 28 is drawn vertically by the rear radial-flow fan 11. From the fan wheel 18 of the radial-flow fan 11, the exhaust air flow 26 emerges in the direction of the air outlet 15 from the rear side 3 of the housing 1. The exhaust air flow 25 and the exhaust air flow 26 emerge essentially parallel from the housing 1. However, the exhaust air flows 25, 26 are separated by the air guide plate 14, so that there is no mixture or mutual interference.

Between the rear side 3 of the housing 1 and the backplane 5, additional narrow plug-in modules can be inserted into the backplane 5 in the installation space 4 from the rear side in. These rear (also not-shown) plug-in modules have a depth of 70 mm. Their power loss is limited by the standard to 15 W per plug-in module. Special ventilation for dissipating the resulting heat loss is not necessary. Therefore, the rear radial-flow fan 11 is arranged in the fan space 8 so that its housing side aligned toward the rear side 3 of the housing 1 essentially closes the backplane 5 in the installation space 4. Therefore, no or only very little air is suctioned from the space formed between the rear side 3 and the backplane 5.

Despite the low power loss of the plug-in modules in the space between the rear side 3 and the backplane 5, it can be necessary to guide a portion of the air flow through this space. This is achieved by providing openings in the bottom region of the backplane 5. In addition, the rear radial-flow fan 11 is pushed to the rear side 3, so that it partially overlaps the space between the rear side 3 and the backplane 5. Alternatively, the rear radial-flow fan 11 can also be slightly inclined from the horizontal. Preferably, the inclination is by about 5°.

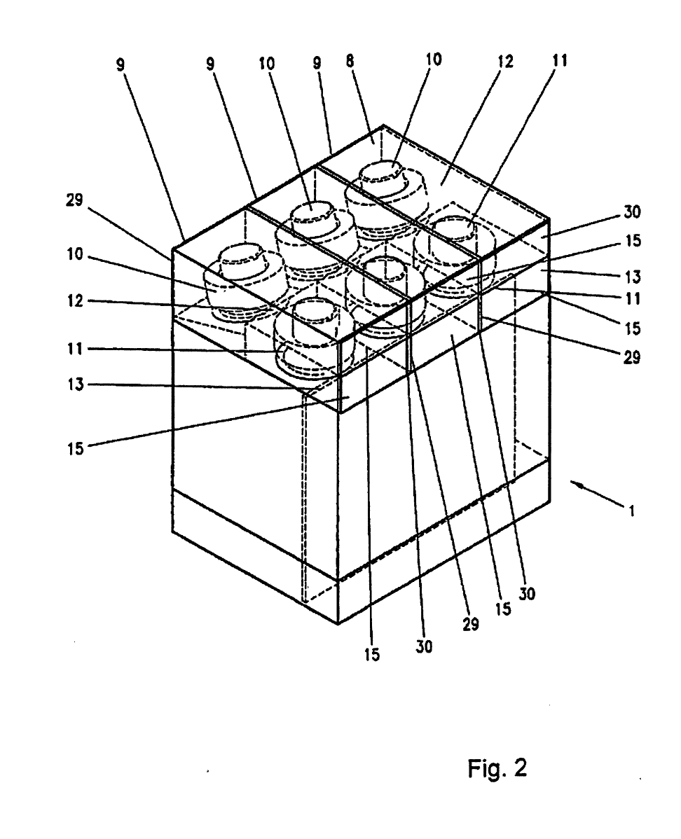

FIG. 2 shows a perspective view of the housing 1 from a rear corner. Three cassettes 9 arranged one next to the other are pushed into the fan space 8. These cassettes each contain a front radial-flow fan 10 and a rear radial-flow fan 11. Thus, in the fan space 8, a matrix made of a total of six radial-flow fans is formed, which are arranged in two rows. Each cassette 9 has a right side wall 29 and a left side wall 30. The side walls 29, 30 each define the sides of the air guidance spaces 12, 13. Thus, the exhaust air flows of all of the radial-flow fans of the individual cassettes 9 are completely decoupled from each other.

Each cassette 9 can be removed individually and independently from the other cassettes out of the housing 1. If a fan becomes defective, the affected cassette 9 is removed from the housing, and the defective fan is replaced. Then the cassette 9 is pushed back into the housing 1. During the exchange of the cassette 9, the exhaust air or cooling output in the housing 1 is reduced by 33%. Thus, the radial-flow fans must be designed so that the components in the installation space 4 do not overheat for a short-term elimination of a third of the cooling power.

In the fan space 8, the air guidance spaces 12, 13 of the individual cassettes 9 can be seen at the rear side 3 of the housing 1. The individual exhaust air flows are led out of the air guidance spaces 12, 13 through the air outlets 15 on the rear side 3 out of the housing 1. A list of reference symbols used herein is as follows:
1 Housing
2 Front side
3 Rear side
4 Installation space
5 Backplane
6 Air suction space
7 Air inlet
8 Fan space
9 Cassette
10 (Front) radial-flow fan
11 (Rear) radial-flow fan
12 Air guidance space (of 10)
13 Air guidance space (of 11) 27 Cooling air flow
14 Air guide plate 28 Cooling air flow
14 a L-leg (of 14) 29 Side wall (of 9)
14 b L-leg (of 14) 30 Side wall (of 9)
15 Air outlet a Inclination angle
16 Mounting plate A Fan axis
17 Fan wheel (of 10)
18 Fan wheel (of 11)
21 Suction head (of 10)
22 Suction head (of 11)
23 Motor housing (of 10)
24 Motor housing (of 11)
25 Exhaust air flow (of 10)
26 Exhaust air flow (of 11)

Although a preferred embodiment has been described in detail those skilled in the art will recognize that various substitutions and modifications may be made without departing from the scope and spirit of the appended claims.

[image]

The present invention relates to a housing for holding electronic plug-in modules, with installation space open toward the front side of the housing for the plug-in modules, an air suction space under the installation space, and a fan space above the installation space, in which at least two radial-flow fans are arranged one behind the other. Cool air flows through the installation space essentially in the vertical direction.

Several such housings are typically installed in switching cabinets. To be able to hold as many housings as possible in one switching cabinet, the individual housings should be as small as possible. The smaller the overall height of the housing, the better the available space in the switching cabinet can be used. In this way, the costs related to the floor space of the switching cabinet can be reduced.

However, at the same time, the packing density of the electronic plug-in modules is continuously increasing due to advances in miniaturization. An increasing number of modules are being placed in smaller and smaller spaces. Thus, the power loss to be dissipated from the plug-in modules is constantly increasing. This results in special cooling requirements for the module carrier and the housing.

Especially in the field of telecommunications devices, cooling requirements have increased very strongly and will continue to increase in the future. The ATCA standard (Advanced Telecom Computing Architecture) developed for telecommunications applications by PICMG (PCI Industrial Computing Manufacture Group) permits power loss of up to 200 W per plug-in module. Typically, in one housing for telecommunications applications, 14 to 16 plug-in modules are placed one next to the other. Thus the total power loss is around 3000 W. To prevent the housing from overheating, this heat energy must be dissipated in an effective and fail-safe way.

The ever increasing power loss stands diametrically against the requirement for an overall height that is as small as possible. To dissipate the heat generated in the module carrier or housing, the cooling output of the cooling system must be increased. This requires the largest and most powerful fans possible. However, more powerful fans accordingly require more space. At the same time, a high cooling output requires large air inlet and outlet cross sections, as well as an air guide shaped favorably for flow with the smallest possible air resistance within the housing. Because the height of the installation space for the plug-in modules is fixed by the standard, the overall height of the housing can be reduced only when the space for the fans is reduced as much as possible. However, this is not possible without additional measures if a very large cooling output is required and a correspondingly more powerful fan with larger dimensions must be used.

As an additional requirement, a system availability of at least 99.999% is expected by the telecommunications systems. Such a high fail-safe performance of a few minutes per year in systems in long-term operation can be guaranteed only with redundant systems. Like all the other important components of a telecommunications system according to the AT-CA standard, the fans must also be designed with multiple redundancy.

From a physical viewpoint, ideal ventilation is generated by a fan with a maximum size. The total efficiency is then greater than for the use of several small fans. However, several small fans reduce the risk of overheating if a single fan fails. If a fan fails, the remaining air output must always be sufficient so that it does not lead to overheating of the system. The air volume reserve must be sufficiently large. Here, a more efficient and technically more useful compromise must be sought between the highest possible air output during normal operation and lowest possible loss of cooling power if a fan fails.

Telecommunications systems in which several small fans are arranged under the plug-in modules in the housing are known. These fans configured as axial-flow fans draw cool air and force it upward onto the plug-in modules. Because incoming cooled air flows around the fans, their temperature load is low, which has a positive effect on the service life.

Housings in which axial-flow fans are arranged above the plug-in modules are known. However, a disadvantage here is that a relatively large space must be made available above the fans so that the exhaust air can be effectively drawn away from the plug-in modules and it does not result in dead air. However, this runs against the requirement for the smallest possible overall height of the overall system.

Instead of axial-flow fans, in the state of the art radial-flow fans are also used which already include a 90° deflection of the air flow due to their construction. The exhaust air drawn from below is blown out to the side. Therefore, no additional space must be made available above the fans. However, because several fans should be used for reasons of redundancy, the fans must be arranged offset in height, so that the exhaust air flows can flow away from the fans unimpaired at the sides, without being impaired by other fans. The more fans that are installed in a row, the greater the necessary height offset of the individual fans relative to each other. The required space for the arrangement of fans must have a height that corresponds to a multiple of the height of a single fan.

A module carrier in which a total of four radial-flow fans are arranged in the fan space above the plug-in modules is produced, for example, by the company Rittal. Each radial-flow fan is installed in a separate capsule. The four radial-flow fans are arranged in two rows, with the front row being mounted above the rear row. Through this arrangement, the fans can be individually exchanged. If one fan fails, 75% of the total cooling output is still available. The exhaust air flow of the front fans is not negatively affected by the rear fans because the exhaust air of the front fans is led away in the horizontal direction above the rear fans. However, this has the disadvantage that the necessary space for the fans must be twice as high as for a single fan cassette.

The problem of the present invention is to devise a housing for holding electronic plug-in modules which has the smallest possible overall height but nevertheless holds several fans for generating a maximum cooling output.

To solve the problem, the invention starts with a housing for holding electronic modules that has an installation space open toward the front side of the housing for plug-in modules, an air suction space under the installation space, and a fan space, which lies above the installation space and in which at least two radial-flow fans are arranged one behind the other. Cool air flows through the installation space essentially in the vertical direction.

The problem is solved by the characterizing features of claim 1.

According to the invention, at least the front radial-flow fan is arranged at an angle so that the exhaust air of the front radial-flow fan flows away essentially above the rear radial-flow fan. By inclining the front radial-flow fan, its exhaust air is not deflected against the rear fan arranged behind the front fan. The inclination must be selected so that the exhaust air flow essentially flows past the rear fan; thus no unnecessary turbulence is created and the air output of the exhaust air flow of the front radial-flow fan is not impaired by the rear fan. In addition, such an arrangement prevents the motor of the rear fan from being heated also by the hot exhaust air flow of the front fan.

In another advantageous embodiment of the housing according to the invention, the rear radial-flow fan is arranged essentially horizontally, while the front radial-flow fan is inclined by an acute angle relative to the horizontal. Thus, the outflow opening of the front fan facing the rear radial-flow fan is increased. The exhaust air flow of the front fan is deflected above the rear fan. The axis of the front radial-flow fan is tilted forward from the vertical, while the axis of the rear fan is essentially vertical. Through the inclined arrangement of the front radial flow, the necessary overall height of the fan space increases only relatively slightly in comparison to the fans arranged horizontally one behind the other. The additional requirement for vertical height is dependent on the degree of inclination of the front radial-flow fan. The inclination angle is determined, in turn, by the diameter and the overall height of the radial-flow fans that are used. For two radial-flow fans arranged offset at an angle one behind the other, the fan space increases only by approximately 50% relative to 100% for fans arranged one above the other. Thus, the spatial requirements are significantly less overall than for two radial-flow fans, which are offset in height and which are both aligned horizontally.

An inclination angle of the front radial-flow fan between 10° and 40° relative to the horizontal is especially preferred. In practical use, an inclination angle of about 30° has proven to be especially preferred. The optimum inclination angle is dependent on the overall height and the size of the individual fan. If more than two fans are used in the housing, the rear radial-flow fan is arranged essentially horizontally. The other fans are inclined relative to the horizontal, with the inclination increasing the closer the radial-flow fan is positioned to the front side of the housing. The optimum inclination of the individual fans also depends on the position and size of the later air outlets.

Advantageously, each radial-flow fan has a separate air guide space. The exhaust air flows of the two radial-flow fans are completely separated from each other, which rules out mixing of the exhaust air flows. Absolutely no turbulence or pneumatic short circuits are produced, which could occur especially when the exhaust air flows have different temperatures. The cooling output and the effectiveness of the radial-flow fans are further increased.

An embodiment of the housing according to the invention in which the fan space holds several cassettes one next to the other, with each cassette containing at least one front radial-flow fan and one rear radial-flow fan, has proven to be especially advantageous. The cassettes can be pushed in and out independently of each other. Each cassette can be exchanged individually. If a single fan fails, one of the cassettes can be removed from the housing, and the fan can be replaced. The other fans or cassettes are not affected by the exchange. Preferably, the cassettes have dividing plates on their sides so that the air flows in the individual cassettes are decoupled from each other. There is no reaction from air guidance in one cassette on other cassettes.

In a preferred embodiment of the housing, the air suction space in the region of the front side of the housing has an air inlet. Fresh air is led through the air inlet of the front side into the housing. The air is then drawn by the fan located above the installation space and flows essentially vertically past the plug-in modules or upward through these modules. The arrangement of the air inlet regions at the front side of the housing has the advantage that they are freely accessible and can be cleaned using simple means and methods if they become dirty. It is also guaranteed that sufficient air can flow into the housing, because the front side of the housing as a rule remains free.

Preferably, the air outlet is located in the region of the rear side of the housing. The air drawn by the fans from below is deflected by 90% [sic; 90°] by the radial-flow fans and fed essentially horizontally through the ventilation channels to the air outlet.

An embodiment of the invention is explained in more detail below with reference to the enclosed figures. Shown are:

FIG. 1, a cross section through a housing with an installation space, a suction space, and a fan space; and

FIG. 2, a perspective view of the housing of FIG. 1.

FIG. 1 shows the housing 1 with its front side 2 and its rear side 3 in section. An installation space 4 is open toward the front side 2 of the housing 1. The installation space 4 is used for holding electronic plug-in modules which are pushed in from the front side 2 into the installation space 4. In the region of the rear side 3 of the installation space 4, there is a rear wiring board, the so-called backplane 5. The (not-shown) plug-in modules are plugged into this backplane 5.

Underneath the installation space 4, there is an air suction space 6. The backplane 5 projects into the rear region of the air suction space 6. In the region of the front side 2, the air suction space 6 has an air inlet 7 through which fresh air can flow into the housing.

Above the installation space 4, there is a fan space 8. In the fan space 8, there are cassettes 9, which include two radial-flow fans 10, 11. The front radial-flow fan 10 is offset at an angle in front of the rear radial-flow fan 11.

The cassette 9 is divided by dividing plates into a front air guidance space 12 and a rear air guidance space 13. The rear air guidance space 13 is formed by an L-shaped air guide plate 14. The long L-leg 14a of the air guide plate 14 is aligned horizontally. Its length corresponds to approximately 60% of the total depth of the housing 1. The short L-leg 14b of the air guide plate 14 extends vertical to the base of the cassette 9. The length of the short L-leg 14b of the air guide plate 14 corresponds to half the height of the cassette 9.

On the rear side 3 of the housing 1, the fan space 8 has an air outlet 15, through which the hot exhaust air is blown out from the housing 1. The cassettes 9 are open at the back. Thus, the air forced through the air guidance spaces 12, 13 of the cassettes 9 can escape into the surroundings.

The front radial-flow fan 10 is mounted on a mounting plate 16. The mounting plate 16 is tilted at an inclination angle α from the horizontal. Consequently, the fan axis A of the front radial-flow fan 10 is tilted by the same angle α from the vertical. The inclination angle α is 30° in the present example. The mounting plate 16 is mounted between the short L-leg 14b of the air guide plate 14 and the front side of the cassette 9. In this way, the mounting plate 16 is attached a few millimeters away from the base of the cassette 9 at the front side of the cassette 9. The opposite end of the mounting plate 16 is attached close to the upper end of the short L-leg 14b of the air guide plate 14.

The radial-flow fans 10, 11 each have a fan wheel 17 and 18, respectively. Underneath the fan wheels 17, 18 there are suction heads 21 and 22, respectively, which draw air in the axial direction. Above the fan wheels 17 and 18, there are the motor housings 23 and 24, respectively, in which the motors for driving the radial-flow fans 10, 11 are located.

The motor housing 24 of the rear radial-flow fan 11 projects through the air guide plate 14 into the front air guidance space 12. The height of the rear air guidance space 13 is thus less than the overall height of the rear radial-flow fan 11.

The inclination angle α of the mounting plate 16 and also the height of the mounting plate 16 above the horizontal are determined by the geometry of the two radial-flow fans 10, 11. The front radial-flow fan 10 is offset at an angle, so that its exhaust air flow 25 flows essentially above the motor housing 24 of the rear radial-flow fan 11. The exhaust air flow 26 of the rear radial-flow fan 11 flows completely in the horizontal direction. An imaginary line running parallel to the bottom side of the air wheel 17 of the front radial-flow fan 10 ends approximately at the front top corner of the motor housing 24 of the rear radial-flow fan 11. So that the exhaust air flow 25 of the front radial-flow fan 10 runs horizontally as much as possible, the inclination angle α is kept as small as possible. The exhaust air flow 25 should be deflected at an angle that is as acute as possible against the cover of the housing 1, so that as little turbulence as possible is generated. Here, a compromise of inclination angle α, height of the mounting plate 16, and overall height of the cassette 9 is sought. The height of the cassette 9 corresponds to twice the height of the rear air guidance space 13.

In FIG. 1, the main air flows of the cooling air or the exhaust air are also shown. The cooling air flows through the air inlet 7 at the front side 2 into the air suction space 6 and then divides into the two cooling air flows 27 or 28. These flow upward from below through the installation space 4 essentially vertically and in this way cool the (not-shown) plug-in modules inserted into the backplane 5. The cooling air flows 27, 28 are drawn by the radial-flow fans 10 and 11, respectively. The front cooling air flow 27 is deflected in the top region of the installation space 4 in the direction of the fan axis A of the front radial-flow fan 10, so that it enters axially into this fan. The air entering the radial-flow fan 10 axially is blown out by the fan wheel 17 radially and flows in the direction of the air outlet 15 via the motor housing 24 of the radial-flow fan 11.

The rear cooling air flow 28 is drawn vertically by the rear radial-flow fan 11. From the fan wheel 18 of the radial-flow fan 11, the exhaust air flow 26 emerges in the direction of the air outlet 15 from the rear side 3 of the housing 1. The exhaust air flow 25 and the exhaust air flow 26 emerge essentially parallel from the housing 1. However, the exhaust air flows 25, 26 are separated by the air guide plate 14, so that there is no mixture or mutual interference.

Between the rear side 3 of the housing 1 and the backplane 5, additional narrow plug-in modules can be inserted into the backplane 5 in the installation space 4 from the rear side in. These rear (also not-shown) plug-in modules have a depth of 70 mm. Their power loss is limited by the standard to 15 W per plug-in module. Special ventilation for dissipating the resulting heat loss is not necessary. Therefore, the rear radial-flow fan 11 is arranged in the fan space 8 so that its housing side aligned toward the rear side 3 of the housing 1 essentially closes the backplane 5 in the installation space 4. Therefore, no or only very little air is suctioned from the space formed between the rear side 3 and the backplane 5.

Despite the low power loss of the plug-in modules in the space between the rear side 3 and the backplane 5, it can be necessary to guide a portion of the air flow through this space. This is achieved by providing openings in the bottom region of the backplane 5. In addition, the rear radial-flow fan 11 is pushed to the rear side 3, so that it partially overlaps the space between the rear side 3 and the backplane 5. Alternatively, the rear radial-flow fan 11 can also be slightly inclined from the horizontal. Preferably, the inclination is by about 5°.

FIG. 2 shows a perspective view of the housing 1 from the rear corner. Three cassettes 9 arranged one next to the other are pushed into the fan space 8. These cassettes each contain a front radial-flow fan 10 and a rear radial-flow fan 11. Thus, in the fan space 8, a matrix made of a total of six radial-flow fans is formed, which are arranged in two rows. Each cassette 9 has a right side wall 29 and a left side wall 30. The side walls 29, 30 each define the sides of the air guidance spaces 12, 13. Thus, the exhaust air flows of all of the radial-flow fans of the individual cassettes 9 are completely decoupled from each other.

Each cassette 9 can be removed individually and independently from the other cassettes out of the housing 1. If a fan becomes defective, the affected cassette 9 is removed from the housing, and the defective fan is replaced. Then the cassette 9 is pushed back into the housing 1. During the exchange of the cassette 9, the exhaust air or cooling output in the housing 1 is reduced by 33%. Thus, the radial-flow fans must be designed so that the components in the installation space 4 do not overheat for a short-term elimination of a third of the cooling power.

In the fan space 8, the air guidance spaces 12, 13 of the individual cassettes 9 can be seen at the rear side 3 of the housing 1. The individual exhaust air flows are led out of the air guidance spaces 12, 13 through the air outlets 15 on the rear side 3 out of the housing 1.

### List of Reference Symbols

1 Housing
2 Front side
3 Rear side
4 Installation space
5 Backplane
6 Air suction space
7 Air inlet
8 Fan space
9 Cassette
10 (Front) radial-flow fan
11 (Rear) radial-flow fan
12 Air guidance space (of 10)
13 Air guidance space (of 11)
14 Air guide plate
14a L-leg (of 14)
14b L-leg (of 14)
15 Air outlet
16 Mounting plate
17 Fan wheel (of 10)
18 Fan wheel (of 11)
21 Suction head (of 10)
22 Suction head (of 11)
23 Motor housing (of 10)
24 Motor housing (of 11)
25 Exhaust air flow (of 10)
26 Exhaust air flow (of 11)
27 Cooling air flow
28 Cooling air flow
29 Side wall (of 9)
30 Side wall (of 9)
α Inclination angle
A Fan axis

1. A housing for holding electronic plug-in modules, with an installation space open toward a front side of the housing for the plug-in modules, an air suction space under the installation space, and a fan space, which lies above the installation space and in which at least two radial-flow fans are arranged one behind the other, wherein cooling air flows essentially in the vertical direction through the installation space, characterized in that a rear radial-flow fan is arranged essentially horizontally and at least the front radial-flow fan is inclined at an acute inclination angle relative to the horizontal so that the exhaust air flow of the front radial-flow fan flows essentially above the rear radial-flow fan.

2. The housing according to claim 1, characterized in that the inclination angle of the front radial-flow fan is between 10° and 40°, preferably approximately 30°, relative to the horizontal.

3. The housing according to claim 1, characterized in that each radial-flow fan has a separate air guidance space.

4. The housing according to claim 1, characterized in that the fan space holds several cassettes one next to the other and the cassettes each contain at least one front radial-flow fan and one rear radial-flow fan.

5. A housing for holding electronic plug-in modules, including an installation space open toward a front side of the housing for the plug-in modules, an air suction space under the installation space, and a fan space disposed above the installation space and in which at least two radial flow fans are arranged one behind the other wherein cooling air flows essentially in a vertical direction through the installation space, the arrangement being characterized in that a rear mounted radial flow fan is arranged essentially horizontally and at least one front mounted radial flow fan is inclined at an acute inclination angle relative to the horizontal such that the exhaust air flow from the front radial flow fan flows generally above the rear radial flow fan, the front radial flow fan being oriented at an angle of between about 10° and 40° relative to the horizontal, each radial flow fan conducting air flow through a separate guidance space, respectively.

6. The housing according to claim 5 characterized in that:
the fan space is operable to receive several cassettes, one next to the other, the cassettes each containing at least one front radial flow fan and one rear radial flow fan.

7. A housing for holding electronic plug-in modules having an installation space open toward a front side of the housing for the plug-in modules, an air suction space under the installation space, and a fan space which lies above the installation space and in which at least two radial flow fans are arranged one behind the other wherein cooling air flows essentially in a vertical direction through the installation space and characterized in that a rear radial flow fan is arranged essentially horizontally and at least one front radial flow fan is inclined at an acute inclination angle relative to the horizontal so that exhaust air flows from the front radial flow fan essentially above the rear radial flow fan and each radial flow fan is provided with a separate air guidance space for the exhaust air flow.

8. The housing according to claim 7 characterized in that:
the fan spaces are operable to hold several cassettes one next to the other, the cassettes each containing at least one front radial flow fan and one rear radial flow fan.

9. The housing according to claim 7 characterized in that:
the inclination angle of the front radial flow fan is between about 10° and 40°.

10. The housing according to claim 9 characterized in that:
the inclination angle of the front radial flow fan is approximately 30° relative to the horizontal.
